(19) United States
(12) Patent Application Publication
(10) Pub. No.: US 2024/0322761 A1
(43) Pub. Date: Sep. 26, 2024

(54) AUTO CALIBRATION CIRCUIT, VARIABLE GAIN AMPLIFIER AND AUTO CALIBRATION METHOD FOR CALIBRATING OUTPUT VOLTAGES OF THE VARIABLE GAIN AMPLIFIER

(71) Applicant: HIMAX TECHNOLOGIES LIMITED, Tainan City (TW)

(72) Inventor: Meng-Chih WENG, Tainan City (TW)

(21) Appl. No.: 18/187,658

(22) Filed: Mar. 21, 2023

(51) Int. Cl. H03F 1/30; H03F 3/45; H03G 3/30

(52) U.S. Cl. CPC H03F 1/30; H03F 3/45475; H03G 3/30; H03G 2201/103

(57) ABSTRACT

The invention provides an auto calibration circuit, a variable gain amplifier and an auto calibration method for calibrating output voltages of the variable gain amplifier, including: a resistor circuit, a reference signal generating circuit and a comparator circuit. The resistor circuit is configured to receive differential voltages from the variable gain amplifier and to convert the differential voltages to a common mode voltage; the reference signal generating circuit includes a calibration resistor for outputting a reference voltage; the comparator circuit is electrically connected to the reference signal generating circuit and the variable gain amplifier, and is configured to receive one of the differential voltages from the variable gain amplifier and to compare the one of the differential voltages with the reference voltage to output a resistance control signal for controlling a variable resistor circuit of the variable gain amplifier.

### BACKGROUND

### Technical Field

The invention relates to an auto calibration circuit, a variable gain amplifier and an auto calibration method for calibrating output voltages of the variable gain amplifier (VGA).

### Description of Related Art

In a communication system, signals may be distorted due to loss or interference in a transmission path when the signals are transmitted from a transmitter to a receiver. In order to recover the distorted signals, an equalizer is generally used in the receiver for signal compensation to improve the reliability of transmitted signals. Further, in the communication system, a variable gain amplifier (VGA) is also used to optimize the voltage amplitude of the transmitted signals.

However, the signal outputted from the VGA to the equalizer may have variable voltage swings. For example, the signals outputted from the VGA have a greater voltage swing at a time point, but have a smaller voltage swing at another time point. The variable voltage swings may be caused due to the great voltage variation of the signals transmitted from the transmitter, due to aging components in the variable gain amplifier, or due to variations of process, voltage or temperature (PVT variations).

### SUMMARY

Thus, the purpose of the invention is to provide an auto calibration circuit, a variable gain amplifier and an auto calibration method for calibrating output voltages of a variable gain amplifier (VGA), which is capable of decreasing the voltage swings outputted from the VGA, thereby stabling the voltages outputted to the equalizer.

According to the purpose of the invention, the auto calibration circuit for calibrating output voltages of the variable gain amplifier includes: a resistor circuit, a reference signal generating circuit and a comparator circuit. The resistor circuit is electrically connected to an output part of the variable gain amplifier, and is configured to receive differential voltages from the output part of the variable gain amplifier and to convert the differential voltages to a common mode voltage; the reference signal generating circuit is electrically connected to the resistor circuit, in which the reference signal generating circuit includes a calibration resistor for outputting a reference voltage; the comparator circuit is electrically connected to the reference signal generating circuit and the output part of the variable gain amplifier, and configured to receive one of the differential voltages from the output part of the variable gain amplifier and to compare the one of the differential voltages with the reference voltage to output a resistance control signal for controlling a variable resistor circuit of the variable gain amplifier.

According to the purpose of the invention, a variable gain amplifier having an auto calibration function includes: a differential pair circuit, a variable resistor circuit and an auto calibration circuit. The auto calibration circuit includes a resistor circuit, a reference signal generating circuit and a comparator circuit. The differential pair circuit includes pull-up resistors, transistors and current sources. The variable resistor circuit is electrically connected to the differential pair circuit, wherein the resistor circuit is configured to adjust differential voltages outputted from the differential pair circuit. The resistor circuit is electrically connected to the differential pair circuit, wherein the resistor circuit is configured to receive the differential voltages from the differential pair circuit and to convert the differential voltages to a common mode voltage. The reference signal generating circuit is electrically connected to the resistor circuit, wherein the reference signal generating circuit comprises a calibration resistor for outputting a reference voltage. The comparator circuit is electrically connected to the reference signal generating circuit and the differential pair circuit, wherein the comparator circuit is configured to receive one of the differential voltages from the differential pair circuit and to compare the one of the differential voltages with the reference voltage to output a resistance control signal for controlling the variable resistor circuit of the variable gain amplifier.

According to the purpose of the invention, an auto calibration method for calibrating output voltages of a variable gain amplifier includes: receiving differential voltages from an output part of the variable gain amplifier; converting the differential voltages to a common mode voltage by using a resistor circuit, wherein the resistor circuit comprises resistors is electrically connected in parallel; outputting a reference voltage by using a reference signal generating circuit, wherein the reference signal generating circuit comprises a calibration resistor and a current source to set the reference voltage to be a desired peak voltage value of the one of the differential voltages in accordance with a user's demand; comparing one of the differential voltages with the reference voltage to output a resistance control signal by using a comparator circuit; and controlling a variable resistor circuit of the variable gain amplifier in accordance with the resistance control signal.

### BRIEF DESCRIPTION OF THE DRAWINGS

FIG. 1 is a schematic diagram of an auto calibration circuit for calibrating output voltages of a variable gain amplifier in an embodiment of the invention.

FIG. 2 is a schematic diagram of a variable resistor circuit in an embodiment of the invention.

FIG. 3 is a schematic diagram of a variable resistor circuit in an embodiment of the invention.

FIG. 4 is a flowchart of an auto calibration method for calibrating output voltages of a variable gain amplifier in an embodiment of the invention.

FIG. 5 is a flowchart of an auto calibration method for calibrating output voltages of a variable gain amplifier in an embodiment of the invention.

FIG. 6 is a schematic diagram of an auto calibration circuit, a variable gain amplifier and an equalizer in an embodiment of the invention.

### DETAILED DESCRIPTION

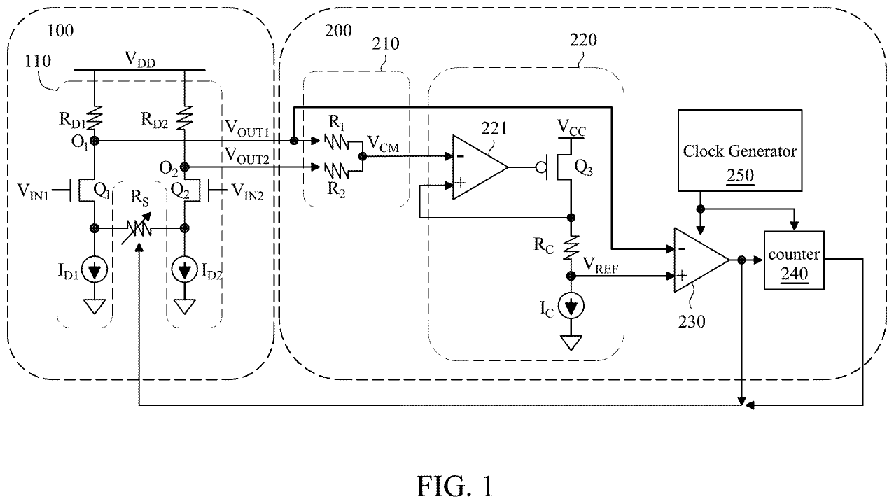

Referring to FIG. 1, FIG. 1 is a schematic diagram showing an auto calibration circuit 200 for calibrating output voltages of a variable gain amplifier 100 in accordance with an embodiment of the present invention. The variable gain amplifier 100 includes a differential pair circuit 110 and a variable resistor circuit R_{S}. The auto calibration circuit 200 includes a resistor circuit 210, a reference signal generating circuit 220 and a comparator circuit 230, which are configured to calibrate the output voltages of the variable gain amplifier 100. When the variable gain amplifier 100 outputs signals having a greater voltage swing, the auto calibration circuit 200 can be used to stabilize the differential signals of the variable gain amplifier 100.

The variable gain amplifier 100 is a differential amplifier circuit configured to reduce common mode noise and to amplify a voltage difference between input terminals, thereby outputting differential voltage signals (output voltages) V_{OUT1} and V_{OUT2}. In an embodiment of the invention, the variable gain amplifier 100 is a source degeneration differential amplifier with a source degeneration resistor (variable resistor circuit) R_{S} to improve linearity. As shown in FIG. 1, the variable gain amplifier 100 is a symmetrical differential pair circuit including two drain resistors R_{D1} and R_{D2} (the drain resistor R_{D1} is the same as the drain resistor R_{D2}), two transistors Q₁ and Q₂ (the transistor Q₁ is the same as the transistor Q₂), two current sources I_{D1} and I_{D2} (the current source I_{D1} is the same as the current source I_{D2}) and the variable resistor circuit R_{S}. The drain resistor R_{D1} is electrically connected between a power supply VDD and a drain of the transistor Q₁, the drain resistor R_{D2} is electrically connected between the power supply VDD and a drain of the transistor Q₂, the current source I_{D1} is electrically connected between a source of the transistor Q₁ and a ground, and the current source I_{D2} is electrically connected between a source of the transistor Q₂ and the ground. The variable resistor circuit R_{S} is electrically connected to the differential pair circuit 110. In this embodiment, the differential pair circuit 110 is designed to be an output part to output differential voltage signals V_{OUT1} and V_{OUT2}. However, embodiments of the present invention are not limited thereto. It should be known that the variable gain amplifier 100 used in the embodiment of the invention can be any differential amplifier with a variable resistor, and the variable resistor has the characteristic of affecting the gain, so the output voltages can be controlled by the auto calibration circuit 200 of the invention.

Referring to FIG. 1, the differential voltage signals V_{OUT1} and V_{OUT2} are generated at the output part of the variable gain amplifier 100 when a differential input signals V_{IN1} and V_{IN2} are supplied to gates of the transistors Q₁ and Q₂ after gain amplification. One of output terminal O₁ of the output part is set between the drain of the transistor Q₁ and the drain resistance R_{D1} to generate the output signal V_{OUT1}, and another output terminal O₂ is set between the drain of the transistor Q₂ and the drain resistance R_{D2} to generate the output signal V_{OUT2}. The gain for the variable gain amplifier 100 is expressed as equation (1):

$$Gain = \frac{{g}_{m} {R}_{D 1}}{1 + {g}_{m} {R}_{S}} = \frac{{g}_{m} {R}_{D 2}}{1 + {g}_{m} {R}_{S}} \qquad ( 1 )$$

It can be found that the gain of the variable gain amplifier 100 is related to the drain resistance (R_{D1}/R_{D2}) and the variable resistor circuit R_{S}, where the drain resistance (R_{D1}/R_{D2}) is set to a fixed value, and the variable resistor circuit R_{S} is much larger than a transfer conductance gₘ. Therefore, the gain of the variable gain amplifier 100 can be calibrated by adjusting a resistance value of the variable resistor circuit R_{S}, thereby achieving the function of calibrating the output voltages V_{OUT1} and V_{OUT2} of the variable gain amplifier 100. It can be known from the equation 1 that the gain is larger when the variable resistor circuit R_{S} is smaller. Conversely, the gain is smaller when the variable resistor circuit R_{S} is larger.

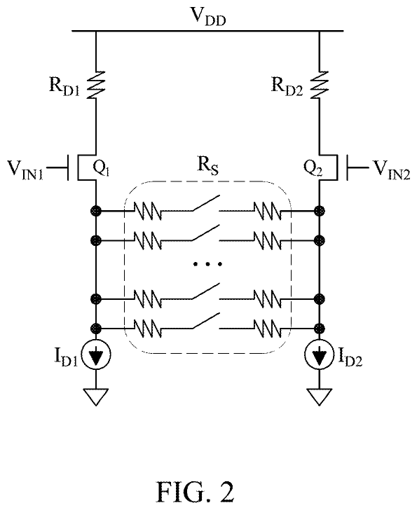

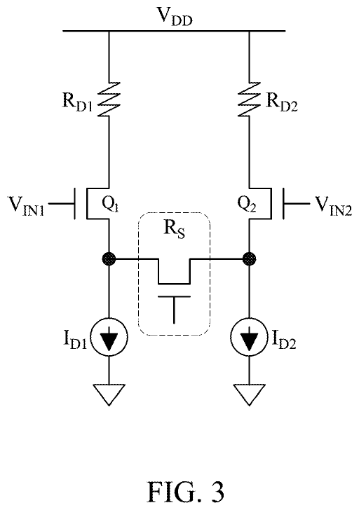

As mentioned above, the gain of the variable gain amplifier 100 can be calibrated by adjusting the resistance value of the variable resistor circuit R_{S}. In an embodiment of the invention, the variable resistor circuit R_{S} includes resistors and transistors in series and parallel. The transistors are used as switches, the more transistors are turned on, the more resistors are electrically connected in parallel, and the resistance value of the variable resistor circuit R_{S} is getting smaller. Conversely, the fewer transistors are turned on, the fewer resistors are electrically connected in parallel, and the resistance value of the variable resistor circuit R_{S} is getting greater. It should be understood that the variable resistor circuit R_{S} can actually be any combination of the transistors and the resistors that can change the resistance value, even there is only one arrangement of the resistors and the transistors shown in FIG. 2. In another embodiment of the invention, the variable resistor circuit R_{S} includes plural transistors as shown in FIG. 3, wherein the transistors are used as a variable resistor and the resistance value is changed by adjusting a gate voltage of the transistors, thereby achieving a gain control of the variable gain amplifier 100.

Referring to FIG. 1, the auto calibration circuit 200 is electrically connected to the output part of the variable gain amplifier 100, and configured to calibrate the output voltages V_{OUT1} and V_{OUT2}, thereby achieving the regulation and calibration of the output voltages V_{OUT1} and V_{OUT2} of the variable gain amplifier 100 for smaller voltage swings.

The first stage of the auto calibration circuit 200 is the resistor circuit 210, which is directly connected to the output part of the variable gain amplifier 100. The first resistor R₁ is electrically connected between the output terminal O₁ and the second resistor R₂, and the second resistor R₂ is electrically connected between the output terminal O₂ and the first resistor R₁. The resistor circuit 210 is configured to convert the output voltages V_{OUT1} and V_{OUT2} to obtain a common mode voltage V_{CM} at a connection point of the first resistor R₁ and the second resistor R₂. The connection point of the first resistor R₁ and the second resistor R₂ is electrically connected to a second stage of the auto calibration circuit 200, and transmit the common mode voltage V_{CM} to the second stage of the auto calibration circuit 200. The common mode voltage V_{CM} is expressed as equation (2):

$${V}_{C M} = \frac{{V}_{OUT 1} + {V}_{OUT 2}}{2} \qquad ( 2 )$$

Please refer to FIG. 1, the second stage of the auto calibration circuit 200 is the reference signal generating circuit 220, which includes an operational amplifier 221, a transistor Q₃, a calibration resistor R_{C} and a calibration current I_{C}. The operational amplifier 221 and the transistor Q₃ are configured to form a feedback circuit. In the embodiment of the invention, a negative terminal of the operational amplifier 221 is electrically connected to the connection point of the first resistor R₁ and the second resistor R₂ of the resistor circuit 210, and receives the common mode voltage V_{CM} divided by the resistor circuit 210. An output terminal of the operational amplifier 221 is electrically connected to a gate of the transistor Q₃, a positive terminal of the operational amplifier 221 is electrically connected to a drain of the transistor Q₃, and a source of the transistor Q₃ is electrically connected to a power supply Vcc. Based on the feedback circuit composed of the operational amplifier 221 and the transistor Q₃, a voltage of the drain of the transistor Q₃ and the positive terminal of the operational amplifier 221 are fixed to the common mode voltage V_{CM}. In this embodiment, the transistor Q₃ is a P-type transistor as shown in FIG. 1, but embodiments of the present invention are not limited thereto.

The reference signal generating circuit 220 of the auto calibration circuit 200 further includes the calibration resistor R_{C} and the calibration current I_{C} to generate a reference voltage V_{REF} in accordance with the common mode voltage V_{CM}. The calibration resistor R_{C} is electrically connected between the transistor Q₃ and the calibration current I_{C}, and the calibration current I_{C} is electrically connected between the calibration resistor R_{C} and the ground. Since a voltage at a connection point between the calibration resistor R_{C} and the transistor Q₃ is the common mode voltage V_{CM}, the relationship between the calibration resistor R_{C}, the calibration current I_{C} and the reference voltage V_{REF} can be calculated. The equation (3) is expressed as follows:

$${I}_{C} \times {R}_{C} = {V}_{C M} - {V}_{R E F} = \frac{a desired output voltages}{2} \qquad ( 3 )$$

In the above equation, the reference voltage V_{REF} is the voltage at the connection point between the calibration resistor R_{C} and the calibration current I_{C}. A voltage drop produced by the calibration resistor R_{C} and the calibration current I_{C} is equal to a difference between the common mode voltage V_{CM} and the reference voltage V_{REF}, which is equal to a half amplitude of the desired output voltages (i.e., a peak voltage value of the one of the differential voltages). Therefore, the output voltages can be controlled by setting the desired output voltages, in which the desired output voltages set by the calibration resistor R_{C} and the calibration current I_{C} according to the requirements.

Please refer to FIG. 1, the third stage of the auto calibration circuit 200 is the comparator circuit 230, which is electrically connected to the reference signal generating circuit 220. The comparator circuit 230 is configured to receive the reference voltage V_{REF} and the one of the output voltages (V_{OUT1}/V_{OUT2}) of the variable gain amplifier 100, and to generate a resistance control signal to the variable resistance circuit R_{S} of the variable gain amplifier 100 according to a comparison result between the reference voltage V_{REF} and the one of the output voltages (V_{OUT1}/V_{OUT2}). The comparator circuit 230 is used to control the resistance value of the variable resistance circuit R_{S}, thereby achieving the output voltages calibration of the variable gain amplifier 100. In the embodiment of the invention, the negative terminal of the comparator circuit 230 is electrically connected to the one of the output terminals (O₁/O₂) of the variable gain amplifier 100, and receives the one of the output voltages (V_{OUT1}/V_{OUT2}). The positive terminal of the comparator circuit 230 is electrically connected to the calibration resistor R_{C} and the calibration current I_{C}, so the positive terminal of the comparator circuit 230 receives the reference voltage V_{REF}. Based on the principle of the comparator circuit 230, the voltages of the positive terminal and the negative terminal are compared, and the resistance control signal is generated to control the resistance value of the variable resistance circuit R_{S}, so that the one of the output voltages (V_{OUT1}/V_{OUT2}) of the variable gain amplifier 100 is calibrated in accordance with the reference voltage V_{REF}. Therefore, the comparator circuit 230 controls the output voltages (V_{OUT1}/V_{OUT2}) of the variable gain amplifier 100 by controlling the resistance value of the variable resistance circuit R_{S}, it will cause the comparator circuit 230 to operate and output the resistance control signal to calibrate the output voltages V_{OUT1} and V_{OUT2}.

In the embodiment of the invention, a counter 240 is further included, which is electrically connected between the variable gain amplifier 100 and the output of the comparator circuit 230. The counter 240 is configured to receive the variable resistance control signal and to count a triggered number according to the resistance control signal, thereby outputting a trigger result to the variable resistance circuit R_{S} of the variable gain amplifier 100, thereby controlling the resistance value of the variable resistance circuit R_{S}. Specifically, the comparator circuit 230 compares the one of the output voltages (V_{OUT1}/V_{OUT2}) of the variable gain amplifier 100 with the reference voltage V_{REF}, and generates the resistance control signal to the counter 240. Then, the counter 240 counts the triggered number according to the resistance control signal, and finally generates the trigger result to the variable resistance circuit R_{S} of the variable gain amplifier 100 to control the transistors of the variable resistance circuit R_{S} (in this embodiment, the transistors are used as switches) to turn on or turn off. When more transistors are turned on, the more resistors are electrically connected in parallel, the smaller the resistance value, the greater the gain, so the output voltages V_{OUT1} and V_{OUT2} will increase. Conversely, when the fewer transistors that are turned on, the less resistors are electrically connected in parallel, the greater the resistance value, the smaller the gain, so the output voltages V_{OUT1} and V_{OUT2} will decrease. Therefore, the output voltages calibration of the variable gain amplifier 100 can be achieved based on the auto calibration circuit 200 as mentioned above.

In another embodiment of the invention, the comparator circuit 230 compares the one of the output voltages (V_{OUT1}/V_{OUT2}) of the variable gain amplifier 100 with the reference voltage V_{REF}, and generates the resistance control signal to the variable resistance circuit R_{S} of the variable gain amplifier 100. The resistance control signal controls the transistors of the variable resistance circuit R_{S} (in this embodiment, the transistors are used as variable resistors), so the gain of the variable gain amplifier 100 can be adjusted to achieve the calibration of the output voltages V_{OUT1} and V_{OUT2}. Therefore, the output voltages calibration of the variable gain amplifier 100 can be achieved based on the auto calibration circuit 200 as mentioned above.

In the embodiment of the invention, a clock generator 250 is further included, which is electrically connected to the comparator circuit 230 and the counter 240. The clock generator 250 is configured to provide a synchronous trigger signal to the comparator circuit 230 and the counter 240. Specifically, the comparator circuit 230 and the counter 240 are activated when the synchronous trigger signal comes.

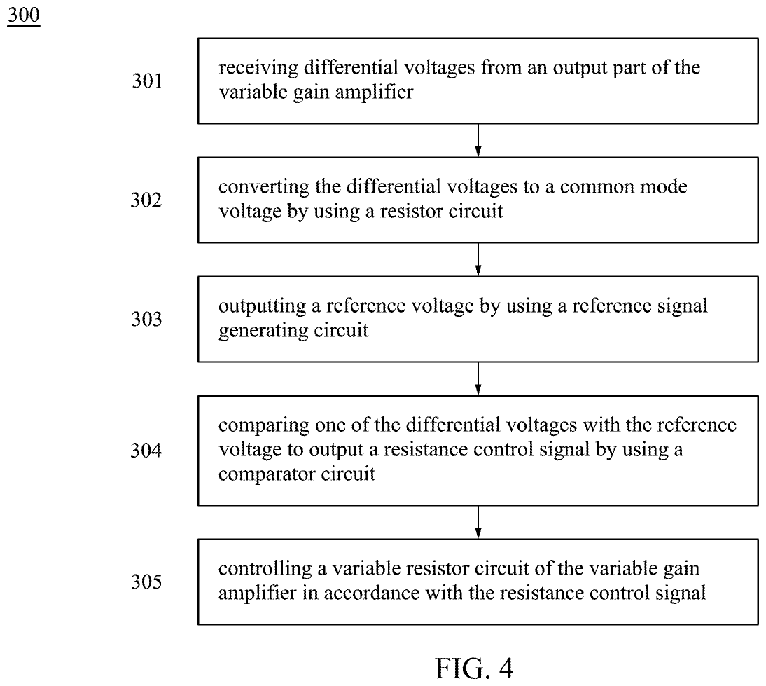

Referring to FIG. 4, a flowchart of an auto calibration method 300 for calibrating output voltages of a variable gain amplifier in an embodiment of the invention is shown. The auto calibration method 300 may be applied to the configuration shown in FIG. 1 or another similar configuration. The following takes the configuration shown in FIG. 1 as an example for description. The auto calibration method 300 for calibrating the output voltages V_{OUT1} and V_{OUT2} of a variable gain amplifier 100 includes steps 301 to 305. First, step 301 is performed to receive the differential voltages V_{OUT1} and V_{OUT2} from an output part of the variable gain amplifier 100. Specifically, the variable gain amplifier 100 is electrically connected to the auto calibration circuit 200. After a differential input voltage is amplified by a gain of the variable gain amplifier 100, the differential voltages is output from the output part of the variable gain amplifier 100, and the differential voltages V_{OUT1} and V_{OUT2} are received by the auto calibration circuit 200.

After step 301 is performed, step 302 is performed to convert the differential voltages V_{OUT1} and V_{OUT2} into a common mode voltage by using a resistor circuit 210. Specifically, the variable gain amplifier 100 is electrically connected to the resistor circuit 210 of the auto calibration circuit 200, and divides the differential voltages V_{OUT1} and V_{OUT2} through the resistor circuit 210 to obtain the common mode voltage V_{CM}.

After step 302 is performed, step 303 is performed to output a reference voltage by using a reference signal generating circuit 220. Specifically, the resistor circuit 210 is electrically connected to the reference signal generating circuit 220, and transmits the common mode voltage V_{CM} to the reference signal generating circuit 220, wherein the reference voltage V_{REF} is calculated according to the common mode voltage V_{CM}, a calibration resistor R_{C} and a calibration current I_{C} of the reference signal generating circuit 220. In the embodiment of the invention, a desired peak voltage value may be set by the calibration current I_{C} and the calibration resistor R_{C} according to the user's needs.

After performing step 303, step 304 is performed to compare the one of the differential voltages with the reference voltage to output a resistance control signal by using a comparator circuit 230. Specifically, the comparator circuit 230 is electrically connected to the reference signal generating circuit 220 and the one of the output terminals (O₁/O₂) of the variable gain amplifier 100, and compares the reference voltage V_{REF} with the one of the output voltages (V_{OUT1}/V_{OUT2}) of the variable gain amplifier 100, thereby generating the resistance control signal.

After performing step 304, step 305 is performed to control a variable resistor circuit R_{S} of the variable gain amplifier 100 in accordance with the resistance control signal. The resistance control signal is generated to control a resistance value of the variable resistance circuit R_{S} of the variable gain amplifier 100. Specifically, the comparator circuit 230 will generate the resistance control signal that increases the variable resistor R_{S} when the one of the output voltages (V_{OUT1}/V_{OUT2}) is greater than the reference voltage V_{REF}, thereby reducing the voltage gain, so the output voltages V_{OUT1} and V_{OUT2} are decreased. Conversely, the comparator circuit 230 will generate the resistance control signal that reduces the resistance R_{S} when the one of the output voltages (V_{OUT1}/V_{OUT2}) is less than the reference voltage V_{REF}, thereby increasing the voltage gain, and thus the output voltages VOUT₁ and V_{OUT2} are increased. Therefore, the output voltages calibration of the variable gain amplifier 100 can be achieved based on the auto calibration method 300 for calibrating output voltages V_{OUT1} and V_{OUT2} of the variable gain amplifier 100 as mentioned above.

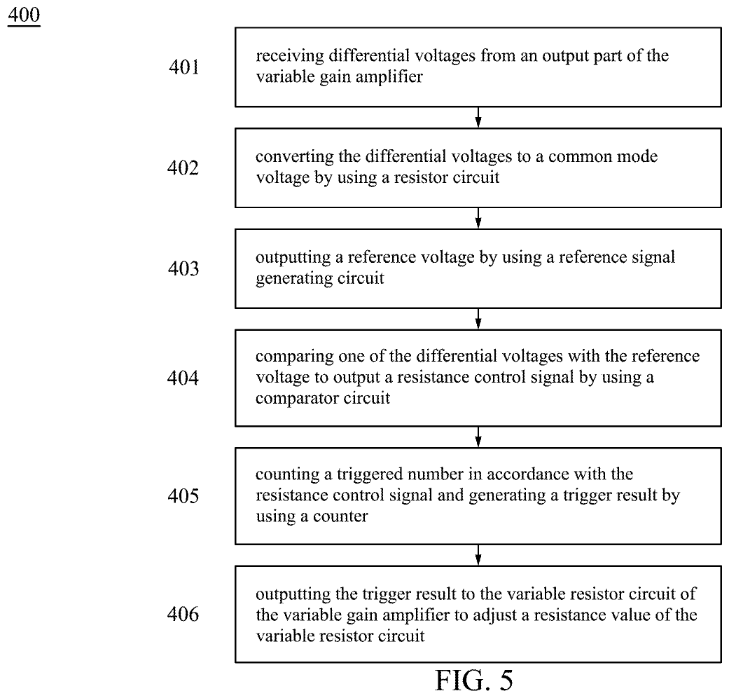

Referring to FIG. 5, an auto calibration method 400 for calibrating output voltages of the variable gain amplifier 100 is shown in another embodiment of the invention. The auto calibration method 400 may be applied to the configuration shown in FIG. 1 or another similar configuration. The following takes the configuration shown in FIG. 1 as an example for description. The auto calibration method 400 for calibrating output voltages V_{OUT1} and V_{OUT2} of the variable gain amplifier 100 includes steps 401 to 406, wherein steps 401 to 404 are the same as steps 301 to 304 in the foregoing embodiment, and will not be repeated here. After performing step 404, step 405 is performed to count a triggered number in accordance with the resistance control signal and generating a trigger result by using a counter 240. Specifically, the comparator circuit 230 compares one of the output voltages (V_{OUT1}/V_{OUT2}) of the variable gain amplifier 100 with the reference voltage V_{REF}, and generates the resistance control signal to the counter 240. Then, the counter 240 counts the triggered number according to the resistance control signal, thereby generating the trigger result.

After performing step 405, step 406 is performed to output the trigger result to the variable resistor circuit R_{S} of the variable gain amplifier 100 to adjust a resistance value of the variable resistor circuit R_{S}. The counter 240 generates the trigger result to the variable resistance circuit R_{S} of the variable gain amplifier 100 to control the transistors of the variable resistance circuit R_{S} (in this embodiment, the transistors are used as switches) to turn on or turn off. Specifically, the counter 240 generates the trigger result that increases the resistance value of the variable resistor circuit R_{S} when the one of the output voltages (V_{OUT1}/V_{OUT2}) is greater than the reference voltage V_{REF}, thereby reducing the voltage gain, so the output voltages V_{OUT1} and V_{OUT2} are decreased. Conversely, the counter 240 generate the trigger result that reduces the resistance value of the variable resistance circuit R_{S} when the one of the output voltages (V_{OUT1}/V_{OUT2}) is less than the reference voltage V_{REF}, thereby increasing the voltage gain, so the output voltages V_{OUT1} and V_{OUT2} are increased. Therefore, the output voltages calibration of the variable gain amplifier 100 can be achieved based on the auto calibration method 400 for calibrating output voltages V_{OUT1} and V_{OUT2} of the variable gain amplifier 100 as mentioned above.

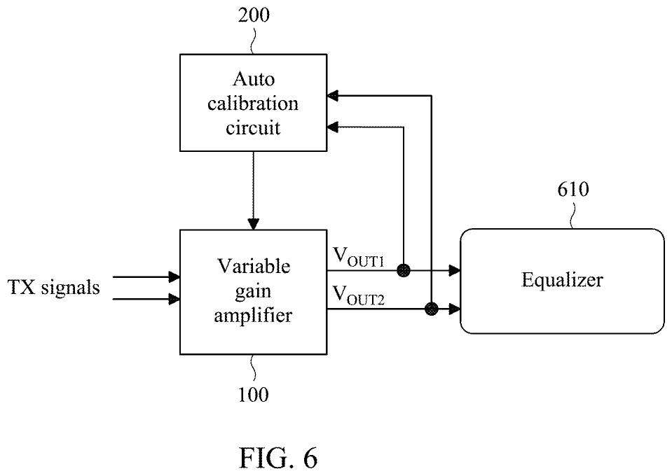

For example, as shown in FIG. 6, the variable gain amplifier 100 is capable of outputting the differential voltages V_{OUT1} and V_{OUT2} having lower voltage swings to an equalizer 610 despite a great voltage swing of the TX signals inputted to the variable gain amplifier 100 or aging components in the variable gain amplifier 100, thereby improving the performance of the equalizer 610.

However, the descriptions are only preferred embodiments of the invention as mentioned above, and should not limit the scope of implementation of the invention. That is, any simple equivalent changes and modifications made according to the scope of the claim and the contents of the description of the invention are still within the scope of the claim of the invention.

What is claimed is:

1. An auto calibration circuit for calibrating output voltages of a variable gain amplifier (VGA), comprising:
a resistor circuit electrically connected to an output part of the variable gain amplifier, wherein the resistor circuit is configured to receive differential voltages from the output part of the variable gain amplifier and to convert the differential voltages to a common mode voltage;
a reference signal generating circuit electrically connected to the resistor circuit, wherein the reference signal generating circuit comprises a calibration resistor for outputting a reference voltage; and
a comparator circuit electrically connected to the reference signal generating circuit and the output part of the variable gain amplifier, wherein the comparator circuit is configured to receive one of the differential voltages from the output part of the variable gain amplifier and to compare the one of the differential voltages with the reference voltage to output a resistance control signal for controlling a variable resistor circuit of the variable gain amplifier.

2. The auto calibration circuit of claim 1, wherein the reference signal generating circuit further comprises:
a first operational amplifier electrically connected to the resistor circuit and configured to receive the common mode voltage;
a transistor electrically connected to an output terminal of the first operational amplifier and configured to form a feedback circuit with the first operational amplifier; and
a current source electrically connected to the calibration resistor and the comparator circuit, and configured to set the reference voltage in accordance with the common mode voltage and the calibration resistor.

3. The auto calibration circuit of claim 2, wherein the calibration resistor and the current source are further configured to set the reference voltage to be a desired peak voltage value of the one of the differential voltages in accordance with a user's demand.

4. The auto calibration circuit of claim 1, further comprising:
a counter electrically connected between the variable gain amplifier and an output of the comparator circuit, wherein the counter is configured to receive the resistance control signal and to count a triggered number in accordance with the resistance control signal, thereby outputting a trigger result to the variable resistor circuit of the variable gain amplifier.

5. The auto calibration circuit of claim 4, further comprising:
a clock generator electrically connected to the comparator circuit and the counter and configured to output a synchronous trigger signal to the comparator circuit and the counter.

6. The auto calibration circuit of claim 4, wherein the variable resistor circuit further comprises a plurality of variable resistor modules which comprise transistors and resistors, and the counter is further configured to output the trigger result to the transistors to control the transistors, thereby controlling a total resistance of the variable resistor circuit.

7. The auto calibration circuit of claim 1, wherein the variable resistor circuit is at least one transistor and a function of the at least one transistor is as a variable resistance, and the comparator circuit is further configured to output the resistance control signal to control the at least one transistor, thereby controlling a total resistance of the variable resistor circuit.

8. A variable gain amplifier having an auto calibration function, comprising:
a differential pair circuit, wherein the differential pair circuit comprises pull-up resistors, transistors and current sources;
a variable resistor circuit electrically connected to the differential pair circuit, wherein the variable resistor circuit is configured to adjusting differential voltages outputted from the differential pair circuit; and
an auto calibration circuit, comprising:
a resistor circuit electrically connected to the differential pair circuit, wherein the resistor circuit is configured to receive the differential voltages from the differential pair circuit and to convert the differential voltages to a common mode voltage;
a reference signal generating circuit electrically connected to the resistor circuit, wherein the reference signal generating circuit comprises a calibration resistor for outputting a reference voltage; and
a comparator circuit electrically connected to the reference signal generating circuit and the differential pair circuit, wherein the comparator circuit is configured to receive one of the differential voltages from the differential pair circuit and to compare the one of the differential voltages with the reference voltage to output a resistance control signal for controlling the variable resistor circuit of the variable gain amplifier.

9. The variable gain amplifier having the auto calibration function of claim 8, wherein the reference signal generating circuit further comprising:
a first operational amplifier electrically connected to the resistor circuit and configured to receive the common mode voltage;
a transistor electrically connected to an output terminal of the first operational amplifier and configured to form a feedback circuit with the first operational amplifier; and
a current source electrically connected to the calibration resistor and the comparator circuit and configured to set the reference voltage in accordance with the common mode voltage and the calibration resistor.

10. The variable gain amplifier having the auto calibration function of claim 8, wherein the reference voltage is set to be a desired peak voltage value of the one of the differential voltages.

11. The variable gain amplifier having the auto calibration function of claim 8, further comprising:
a counter electrically connected between the variable resistor circuit and an output of the comparator circuit, wherein the counter is configured to receive the resistance control signal and to count a triggered number in accordance with the resistance control signal, thereby outputting a trigger result to the variable resistor circuit of the variable gain amplifier.

12. The variable gain amplifier having the auto calibration function of claim 11, wherein the variable resistor circuit further comprises a plurality of variable resistor modules which comprise transistors and resistors, and the counter is further configured to output the trigger result to the transistors to control the transistors, thereby controlling a total resistance of the variable resistor circuit.

13. The variable gain amplifier having the auto calibration function of claim 8, wherein the variable resistor circuit is at least one transistor and a function of the at least one transistor is as a variable resistance, and the comparator circuit is further configured to output the resistance control signal to control the at least one transistor, thereby controlling a total resistance of the variable resistor circuit.

14. An auto calibration method for calibrating output voltages of a variable gain amplifier, comprising:
receiving differential voltages from an output part of the variable gain amplifier;
converting the differential voltages to a common mode voltage by using a resistor circuit, wherein the resistor circuit comprises resistors electrically connected in parallel;
outputting a reference voltage by using a reference signal generating circuit, wherein the reference signal generating circuit comprises a calibration resistor and a current source to set the reference voltage to be a desired peak voltage value of the one of the differential voltages in accordance with a user's demand;
comparing the one of the differential voltages with the reference voltage to output a resistance control signal by using a comparator circuit; and
controlling a variable resistor circuit of the variable gain amplifier in accordance with the resistance control signal.

15. The auto calibration method for calibrating the output voltages of the variable gain amplifier of claim 14, further comprising:
counting a triggered number in accordance with the resistance control signal by using a counter to generate a trigger result;
wherein controlling the variable resistor circuit of the variable gain amplifier in accordance with the resistance control signal comprises: outputting the trigger result to the variable resistor circuit of the variable gain amplifier to adjust a resistance value of the variable resistor circuit.

16. The auto calibration method for calibrating the output voltages of the variable gain amplifier of claim 15, further comprising:
providing a synchronous trigger signal to the comparator circuit and the counter by using a clock generator.
